(19) United States
(12) Patent Application Publication
(10) Pub. No.: US 2024/0405732 A1
(43) Pub. Date: Dec. 5, 2024

(54) HIGH FREQUENCY CIRCUIT AND COMMUNICATION APPARATUS

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/804,088

(22) Filed: Aug. 14, 2024

Related U.S. Application Data
(63) Continuation of application No. PCT/JP2023/003858, filed on Feb. 6, 2023.

(30) Foreign Application Priority Data
Feb. 17, 2022 (JP) 2022-022984

(51) Int. Cl. H03F 3/21; H03F 1/02; H03F 1/56; H03F 3/213; H04B 1/00; H04B 1/04

(52) U.S. Cl. CPC H03F 3/211; H03F 1/0288; H03F 1/56; H03F 3/213; H04B 1/0057; H04B 1/04; H03F 2200/211; H03F 2200/318; H03F 2200/451; H03F 2200/541

(57) ABSTRACT

A high frequency circuit includes a signal input terminal and a signal output terminal; a first amplifier, a second amplifier, a third amplifier, and a fourth amplifier; and a first phase shift circuit. An input terminal of the fourth amplifier is connected to the signal input terminal, an output terminal of the fourth amplifier is connected to an input terminal of the first amplifier and an input terminal of the second amplifier, an output terminal of the second amplifier is connected to an input terminal of the third amplifier, an output terminal of the third amplifier is connected to one end of the first phase shift circuit, and the other end of the first phase shift circuit is connected to an output terminal of the first amplifier.

### CROSS-REFERENCE TO RELATED APPLICATIONS

The present application is a continuation application of PCT International Application No. PCT/JP2023/003858, filed on Feb. 6, 2023, designating the United States of America, which is based on and claims priority to Japanese patent application JP 2022-022984, filed Feb. 17, 2022. The entire disclosures of the above-identified applications, including the specifications, the drawings, and the claims are incorporated herein by reference in their entirety.

### BACKGROUND

A high frequency circuit (power amplification circuit) may include a first amplifier (carrier amplifier) that amplifies a first signal split from an input signal, in a region in which a power level of the input signal is equal to or higher than a first level, to output a second signal, a first transformer to which the second signal is input, a second amplifier (peak amplifier) that amplifies a third signal split from the input signal, in a region in which the power level of the input signal is equal to or higher than a second level higher than the first level, to output a fourth signal, and a second transformer to which the fourth signal is input.

### SUMMARY

An aspect of the present disclosure provides a high frequency circuit including: a signal input terminal and a signal output terminal; a first amplifier, a second amplifier, a third amplifier, and a fourth amplifier; and a first phase shift circuit, wherein an input terminal of the fourth amplifier is connected to the signal input terminal, an output terminal of the fourth amplifier is connected to an input terminal of the first amplifier and an input terminal of the second amplifier, an output terminal of the second amplifier is connected to an input terminal of the third amplifier, an output terminal of the third amplifier is connected to one end of the first phase shift circuit, and the other end of the first phase shift circuit is connected to an output terminal of the first amplifier.

Another aspect of the present disclosure provides a high frequency circuit including: a semiconductor integrated circuit (IC) including a first amplifier, a second amplifier, a third amplifier, and a fourth amplifier, wherein, in a plan view of a main surface of the semiconductor IC, the second amplifier is disposed between the first amplifier and the third amplifier.

Another aspect of the present disclosure provides a high frequency circuit including: a first amplifier that amplifies a first high frequency signal to output a first amplified signal; a second amplifier that amplifies the first high frequency signal to output a second amplified signal; a third amplifier that amplifies the second amplified signal to output a third amplified signal; and a combining circuit that combines the first amplified signal and the third amplified signal to output a combined signal.

### BRIEF DESCRIPTION OF DRAWINGS

FIG. 1 is a circuit configuration diagram of a high frequency circuit and a communication apparatus according to an exemplary embodiment.

FIG. 2A is a circuit state diagram of an amplification circuit according to the exemplary embodiment when a large signal is input.

FIG. 2B is a circuit state diagram of the amplification circuit according to the exemplary embodiment when a small signal is input.

FIG. 3 is a circuit configuration diagram of a high frequency circuit according to a comparative example 1.

FIG. 4 is a graph illustrating a relationship between output power and efficiency in the high frequency circuits according to the exemplary embodiment and the comparative example 1.

FIG. 5 is a circuit configuration diagram of a high frequency circuit according to a modification example 1.

FIG. 6 is a circuit configuration diagram of a high frequency circuit according to a modification example 2.

FIG. 7 is a circuit configuration diagram of a high frequency circuit according to a modification example 3.

FIG. 8A is a circuit state diagram of the amplification circuit according to the modification example 3 when a large signal is input.

FIG. 8B is a circuit state diagram of the amplification circuit according to the modification example 3 when a medium signal is input.

FIG. 8C is a circuit state diagram of the amplification circuit according to the modification example 3 when a small signal is input.

FIG. 9 is a circuit configuration diagram of an amplification circuit according to a modification example 4.

FIG. 10 is a circuit configuration diagram of an amplification circuit according to a modification example 5.

FIG. 11 is a plan view of amplification circuits according to the modification example 5 and a comparative example 2.

### DESCRIPTION OF EXEMPLARY EMBODIMENTS

However, in a case of the high frequency circuit described above, an operation of the second amplifier may deviate from a desired operating point, and the efficiency may deteriorate or the maximum output power may be insufficient.

The present disclosure has been made in order to address this situation, and an aspect of the present disclosure is to provide a high frequency circuit and a communication apparatus in which the deterioration in the efficiency and the maximum output power is suppressed.

According to the present disclosure, it is possible to provide the high frequency circuit and the communication apparatus in which the deterioration in efficiency and the maximum output power is suppressed.

Hereinafter, an exemplary embodiment of the present disclosure will be described in detail. The following exemplary embodiment is an inclusive or specific example. Numerical values, shapes, materials, constituent elements, disposition and connection forms of the constituent elements, and the like described in the following exemplary embodiment are examples and are not intended to limit the gist of the present disclosure. Among the constituent elements in the following examples and modification examples, a constituent element that is not present in an independent claim is described as an optional constituent element. In addition, sizes or size ratios of the constituent elements illustrated in drawings are not necessarily exact. In each drawing, substantially the same configurations are denoted by the same reference numerals, and duplicate description may be omitted or simplified.

Further, in the following description, terms such as “parallel” and “perpendicular”, representing a relationship between elements, a term such as “rectangular” representing the shape of the element, and a numerical value range include not only their exact meaning but also a substantially equivalent range, for example, the inclusion of an error of about a few percent.

In the following drawings, an x-axis and a y-axis are axes orthogonal to each other on a plane parallel to a main surface of a module substrate. Specifically, in a case where the module substrate is rectangular in a plan view, the x-axis is parallel to a first edge of the module substrate, and the y-axis is parallel to a second edge of the module substrate orthogonal to the first edge. In addition, a z-axis is an axis perpendicular to the main surface of the module substrate, and a positive direction thereof indicates an up direction, and a negative direction thereof indicates a down direction.

In a circuit configuration of the present disclosure, the expression “connected” includes a case of being electrically connected with another circuit element interposed therebetween, as well as a case of being directly connected by a connection terminal and/or a wiring conductor. The expression “connected between A and B” includes a connection to both A and B between A and B, a serial connection to a path that connects A and B, as well as a parallel connection (shunt connection) between the path and a ground.

In the circuit configuration of the present disclosure, the expression “the component A is disposed in series to a path B” indicates that both a signal input end and a signal output end of the component A are connected to a wiring, an electrode, or a terminal constituting the path B.

In the component disposition of the present disclosure, the expression “in plan view of the module substrate” indicates that an object is seen in an orthogonally projected manner onto an xy plan from the z-axis positive side. The expression “A is disposed between B and C” indicates that at least one of a plurality of line segments connecting any point in B and any point in C passes through A. The expression “a distance between A and B in plan view of the module substrate” indicates a length of a line segment connecting a representative point in a region of A and a representative point in a region of B that are orthogonally projected onto the xy plane. In this case, as the representative point, a center point of the region, a point closest to the other region, or the like can be used, but the present disclosure is not limited thereto.

In the component disposition of the present disclosure, the expression “the component is disposed on the substrate” indicates that the component is disposed on the main surface of the substrate and that the component is disposed in the substrate. The expression “the component is disposed on the main surface of the substrate” includes that the component is disposed above the main surface without being in contact with the main surface (for example, the component is laminated on another component disposed in contact with the main surface), in addition to meaning that the component is disposed in contact with the main surface of the substrate. The expression “the component is disposed on the main surface of the substrate” may indicate that the component is disposed in a recess portion formed in the main surface. The expression “the component is disposed in the substrate” includes that the entire component is disposed between both main surfaces of the substrate, but a part of the component is not covered with the substrate, and only a part of the component is disposed in the substrate, in addition to meaning that the component is encapsulated in the module substrate.

In the present disclosure, the term “signal path” includes a transmission line configured with a wiring through which a high frequency signal propagates, an electrode directly connected to the wiring, a terminal directly connected to the wiring or to the electrode, and the like.

### Exemplary Embodiment

### [1. Circuit Configurations of High Frequency Circuit 1 and Communication Apparatus 4]

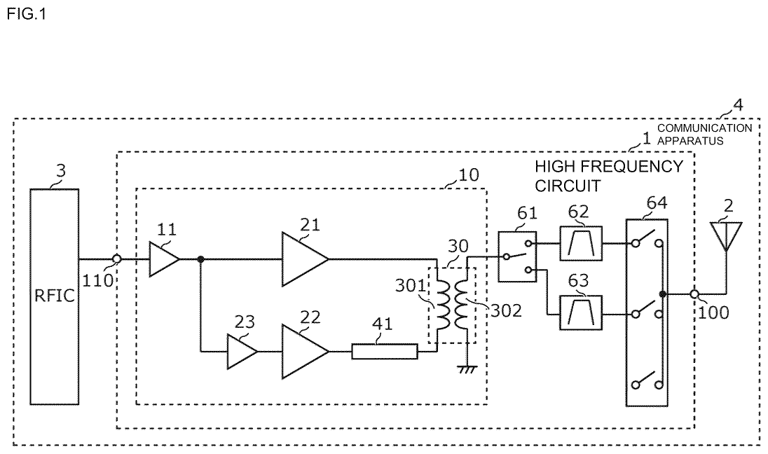

Circuit configurations of a high frequency circuit 1 and a communication apparatus 4 according to the present exemplary embodiment will be described with reference to FIG. 1. FIG. 1 is a circuit configuration diagram of the high frequency circuit 1 and the communication apparatus 4 according to the exemplary embodiment.

### [1.1 Circuit Configuration of Communication Apparatus 4]

First, the circuit configuration of the communication apparatus 4 will be described. As illustrated in FIG. 1, the communication apparatus 4 according to the present exemplary embodiment includes the high frequency circuit 1, an antenna 2, and a RF signal processing circuit (RFIC) 3.

The high frequency circuit 1 transmits a high frequency signal between the antenna 2 and the RFIC 3. The detailed circuit configuration of the high frequency circuit 1 will be described later.

The antenna 2 is connected to an antenna connection terminal 100 of the high frequency circuit 1, transmits the high frequency signal output from the high frequency circuit 1, and receives the high frequency signal from an outside to output the high frequency signal to the high frequency circuit 1.

The RFIC 3 is an example of a signal processing circuit that processes the high frequency signal. Specifically, the RFIC 3 performs signal processing on a reception signal input through a reception path of the high frequency circuit 1 by down-conversion or the like, and outputs the reception signal generated through the signal processing to a baseband signal processing circuit (BBIC, not illustrated). In addition, the RFIC 3 performs signal processing on a transmission signal input from the BBIC by up-conversion or the like, and outputs the transmission signal generated through the signal processing to a transmission path of the high frequency circuit 1. In addition, the RFIC 3 has a control unit that controls a switch, an amplification element, and the like included in the high frequency circuit 1. Some or all of the functions of the control unit of the RFIC 3 may be implemented outside the RFIC 3, and may be implemented in, for example, the BBIC or the high frequency circuit 1.

In addition, the RFIC 3 also has a function as a control unit that controls a power supply voltage Vcc and a bias voltage Vbias supplied to each of amplifiers included in the high frequency circuit 1. Specifically, the RFIC 3 outputs a digital control signal to the high frequency circuit 1. Each of the amplifiers of the high frequency circuit 1 is supplied with the power supply voltage Vcc and the bias voltage Vbias, which are controlled by the digital control signal.

In addition, the RFIC 3 also has a function as a control unit that controls the connection between switches 61 and 64 included in the high frequency circuit 1 based on a communication band (frequency band) to be used.

In the communication apparatus 4 according to the present exemplary embodiment, the antenna 2 is not an essential constituent element.

### [1.2 Circuit Configuration of High Frequency Circuit 1]

Next, the circuit configuration of the high frequency circuit 1 will be described. As illustrated in FIG. 1, the high frequency circuit 1 includes an amplification circuit 10, filters 62 and 63, the switches 61 and 64, an input terminal 110 (signal input terminal), and an antenna connection terminal 100 (signal output terminal).

The input terminal 110 is connected to the RFIC 3, and the antenna connection terminal 100 is connected to the antenna 2. Each of the input terminal 110 and the antenna connection terminal 100 may be a metal conductor such as a metal electrode and a metal bump, or may be a single point on a metal wiring.

The amplification circuit 10 is a Doherty amplification circuit that amplifies the transmission signals of a band A and a band B input from the input terminal 110. The high frequency circuit 1 may include a first Doherty amplification circuit that amplifies the high frequency signal of the band A and a second Doherty amplification circuit that amplifies the high frequency signal of the band B, instead of the amplification circuit 10.

The Doherty amplification circuit is an amplification circuit that realizes high efficiency by using a plurality of amplifiers as a carrier amplifier and a peak amplifier. The carrier amplifier is an amplifier that operates regardless of whether the power of the high frequency signal (input) is low or high in the Doherty amplification circuit. The peak amplifier is an amplifier that mainly operates in a case where the power of the high frequency signal (input) is high in the Doherty amplification circuit. Therefore, the high frequency signal is mainly amplified by the carrier amplifier in a case where the input power of the high frequency signal is low, and the high frequency signals are amplified by the carrier amplifier and the peak amplifier and are combined in a case where the input power of the high frequency signal is high. Due to such an operation, in the Doherty amplification circuit, a load impedance seen from the carrier amplifier is increased at low output power, and the efficiency at low output power is improved.

In the high frequency circuit according to the present disclosure, in a case in which an output signal of the carrier amplifier and an output signal of the peak amplifier are voltage-combined, it is specified that an amplifier having an output terminal connected to a phase shift circuit that shifts a phase of the high frequency signal by a ¼ wavelength is the peak amplifier, and an amplifier having no output terminal connected to the phase shift circuit that shifts the phase of the high frequency signal by a ¼ wavelength is the carrier amplifier. In addition, in the high frequency circuit according to the present disclosure, in a case where the output signal of the carrier amplifier and the output signal of the peak amplifier are current-combined, it is specified that an amplifier having the output terminal connected to the phase shift circuit that shifts the phase of the high frequency signal by a ¼ wavelength is the carrier amplifier, and an amplifier having no output terminal connected to the phase shift circuit that shifts the phase of the high frequency signal by a ¼ wavelength is the peak amplifier.

In the present exemplary embodiment, each of the band A and the band B include a frequency band defined in advance by a standards organization or the like (for example, 3rd generation partnership project (3GPP) (registered trademark), institute of electrical and electronics engineers (IEEE), or the like) for a communication system constructed by using a radio access technology (RAT). In the present exemplary embodiment, as the communication system, for example, a 4th generation (4G)-long term evolution (LTE) system, a 5th generation (5G)-new radio (NR) system, a wireless local area network (WLAN) system, and the like can be used, but the present disclosure is not limited thereto.

The filter 62 is connected between the switches 61 and 64, and allows the transmission signal of the transmission band of the band A to pass among the transmission signals amplified by the amplification circuit 10. The filter 63 is connected between the switches 61 and 64, and allows the transmission signal of the transmission band of the band B to pass among the transmission signals amplified by the amplification circuit 10.

Each of the filters 62 and 63 may be configured as a duplexer along with a reception filter, or may be one filter that performs transmission in a time division duplex (TDD) system. In a case in which the filters 62 and 63 are filters for the TDD, a switch for switching between the transmission and the reception is disposed in at least one of a preceding stage or a subsequent stage of the one filter.

The switch 61 has a common terminal, a first selection terminal, and a second selection terminal. The common terminal is connected to the amplification circuit 10. The first selection terminal is connected to the filter 62, and the second selection terminal is connected to the filter 63. In this connection configuration, the switch 61 switches the connection between the amplification circuit 10 and the filter 62 and the connection between the amplification circuit 10 and the filter 63.

The switch 64 is an example of an antenna switch, is connected to the antenna connection terminal 100, switches the connection and disconnection between the antenna connection terminal 100 and the filter 62, and switches the connection and disconnection between the antenna connection terminal 100 and the filter 63.

The high frequency circuit 1 may include a reception circuit for transmitting the reception signal received from the antenna 2 to the RFIC 3. In this case, the high frequency circuit 1 includes a low noise amplifier and a reception filter.

An impedance matching circuit may be disposed between the amplification circuit 10 and the antenna connection terminal 100.

With the above-described circuit configuration, the high frequency circuit 1 can transmit or receive any of the high frequency signals of the band A or the band B. Further, the high frequency circuit 1 can also execute at least any of simultaneous transmission, simultaneous reception, or simultaneous transmission and reception of the high frequency signals of the band A and the band B.

The high frequency circuit 1 according to the present disclosure need only include at least the amplification circuit 10 in the circuit configuration illustrated in FIG. 1.

Here, the circuit configuration of the amplification circuit 10 will be described in detail.

As illustrated in FIG. 1, the amplification circuit 10 includes a carrier amplifier 21, a peak amplifier 22, preamplifiers 11 and 23, a phase shift line 41, and a transformer 30.

The carrier amplifier 21 is an example of a first amplifier according to the present exemplary embodiment and amplifies the high frequency signal of the band A or the band B input to the carrier amplifier 21. The carrier amplifier 21 is, for example, an A-class (or AB-class) amplification circuit that can perform an amplification operation for all of the power levels of the signal input to the carrier amplifier 21, and particularly, can perform a highly efficient amplification operation in the low-output region and a medium-output region.

The peak amplifier 22 is an example of a third amplifier according to the present exemplary embodiment and amplifies the high frequency signal of the band A or the band B input to the peak amplifier 22. The peak amplifier 22 is, for example, a C-class amplification circuit that can perform an amplification operation in a region in which the power level of the signal input to the peak amplifier 22 is high. Since a bias voltage lower than a bias voltage applied to an amplification transistor included in the carrier amplifier 21 is applied to an amplification transistor included in the peak amplifier 22, an output impedance is lower as the power level of the signal input to the peak amplifier 22 is higher. As a result, the peak amplifier 22 can perform the amplification operation with low distortion in the high-output region.

The carrier amplifier 21 and the peak amplifier 22 each include an amplification transistor. The amplification transistor is, for example, a bipolar transistor such as a heterojunction bipolar transistor (HBT) or an electric field effect transistor such as a metal-oxide-semiconductor field effect transistor (MOSFET).

The preamplifier 11 is an example of a fourth amplifier according to the present exemplary embodiment and amplifies the high frequency signal of the band A or the band B input from the input terminal 110. The preamplifier 11 is, for example, an A-class (or AB-class) amplification circuit that can perform an amplification operation for all of the power levels of the signal input to the preamplifier 11. For example, a bias voltage higher than the bias voltage applied to the amplification transistor included in the peak amplifier 22 is applied to an amplification transistor included in the preamplifier 11.

The preamplifier 23 is an example of a second amplifier according to the present exemplary embodiment and amplifies the high frequency signal of the band A or the band B input to the preamplifier 23. The preamplifier 23 is, for example, an A-class (or AB-class) amplification circuit that can perform an amplification operation for all of the power levels of the signal input to the preamplifier 23. For example, a bias voltage higher than the bias voltage applied to an amplification transistor included in the peak amplifier 22 is applied to the amplification transistor included in the preamplifier 23.

The transformer 30 is an example of a first transformer and has an input side coil 301 (first input side coil) and an output side coil 302 (first output side coil).

The phase shift line 41 is an example of a first phase shift circuit, and is, for example, a ¼ wavelength transmission line. The phase shift line 41 delays the phase of the high frequency signal input from one end thereof by a ¼ wavelength and outputs the high frequency signal from the other end thereof. The first phase shift circuit need not have a form of the phase shift line 41, and may be, for example, a circuit configured with chip-shaped inductor and capacitor. More specifically, the first phase shift circuit may be an LC circuit including two inductors connected in series to each other and a capacitor connected between a connecting point of the two inductors and the ground. In addition, the first phase shift circuit may be an LC circuit including two capacitors connected in series to each other, an inductor connected between one end of one capacitor of the two capacitors and the ground, and an inductor connected between the other end of the one capacitor and the ground.

An input terminal of the preamplifier 11 is connected to the input terminal 110, and an output terminal of the preamplifier 11 is connected to an input terminal of the carrier amplifier 21 and an input terminal of the preamplifier 23. An output terminal of the preamplifier 23 is connected to an input terminal of the peak amplifier 22. An output terminal of the carrier amplifier 21 is connected to one end of the input side coil 301, and an output terminal of the peak amplifier 22 is connected to one end of the phase shift line 41. The other end of the phase shift line 41 is connected to the other end of the input side coil 301. One end of the output side coil 302 is connected to the antenna connection terminal 100 with the switches 61 and 64 and the filters 62 and 63 interposed therebetween, and the other end of the output side coil 302 is connected to the ground.

The preamplifier 23 is disposed on an input side (preceding stage) of the peak amplifier 22 and functions as a drive amplifier of the peak amplifier 22, but is connected to the output terminal of the preamplifier 11 that functions as a drive amplifier of the carrier amplifier 21. Therefore, the amplification operation and the behavior of the output signal of the preamplifier 23 reflect the behavior of the output signal of the preamplifier 11. That is, it can be said that the preamplifier 11 and the preamplifier 23 perform a so-called pair operation from the viewpoint that the behavior of the output signal is the same.

The amplification transistor included in the preamplifier 23 may be formed in a forming region of the amplification transistor included in the carrier amplifier 21. The forming region of the amplification transistor is defined as, for example, a region in which a base, an emitter, and a collector are formed in a case where the amplification transistor is the bipolar transistor. In addition, the configuration in which the amplification transistor included in the preamplifier 23 is formed in the forming region of the amplification transistor included in the carrier amplifier 21 indicates that at least one of a base, an emitter, and a collector constituting the amplification transistor included in the preamplifier 23 is shared with at least a part of a base, an emitter, or a collector constituting the amplification transistor included in the carrier amplifier 21. Accordingly, it can be said that the preamplifier 23 and the carrier amplifier 21 perform a so-called pair operation from the viewpoint that the forming regions of the amplification transistors are shared.

With the above-described connection configuration of the high frequency circuit 1, the signal of the band A output from the carrier amplifier 21 and the signal of the band A output from the peak amplifier 22 are voltage-combined, and the voltage-combined output signal is output to the switch 61. Further, the signal of the band B output from the carrier amplifier 21 and the signal of the band B output from the peak amplifier 22 are voltage-combined, and the voltage-combined output signal is output to the switch 61.

The high frequency circuit 1 according to the present exemplary embodiment is a high frequency circuit having a Doherty amplifier, the high frequency circuit includes the carrier amplifier 21 that amplifies the first high frequency signal to output a first amplified signal, the preamplifier 23 that amplifies the first high frequency signal to output a second amplified signal, a peak amplifier 22 that amplifies the second amplified signal to output a third amplified signal, and a combining circuit that combines the first amplified signal and the third amplified signal to output a combined signal. The above-described combining circuit is the transformer 30 and the phase shift line 41.

### [1.3 Operation of Amplification Circuit 10]

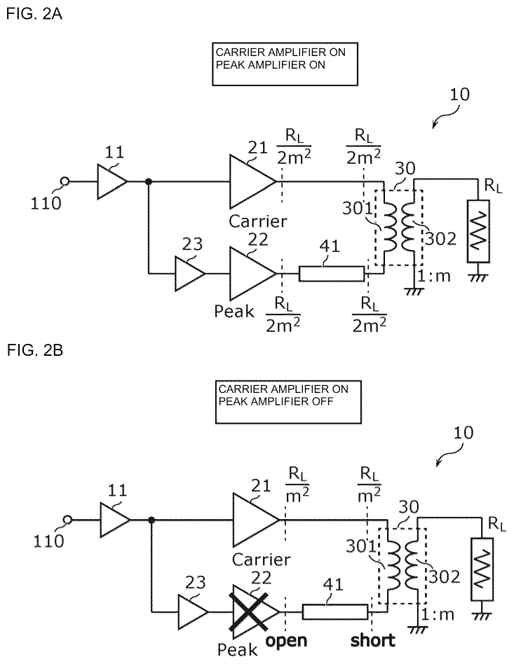

FIG. 2A is a circuit state diagram of the amplification circuit 10 according to the exemplary embodiment when a large signal is input. FIG. 2B is a circuit state diagram of the amplification circuit 10 according to the exemplary embodiment when a small signal is input.

First, as illustrated in FIG. 2A, in a case where the carrier amplifier 21 and the peak amplifier 22 operate (ON) (when a large signal is input), the output impedances when a load side is seen from the output terminals of the carrier amplifier 21 and the peak amplifier 22 are represented by R_{L}/2m². The transformer 30 performs transformation at a ratio of 1:m. In addition, an impedance of a load connected to one end of the output side coil 302 is R_{L}.

Next, as illustrated in FIG. 2B, in a case where the carrier amplifier 21 operates (ON) and the peak amplifier 22 does not operate (OFF) (when a small signal is input), the output impedance when the load side is seen from the output terminal of the carrier amplifier 21 is represented by R_{L}/m². In this case, the output impedance when the load side is seen from the output terminal of the peak amplifier 22 is in an open state.

As described above, when a small signal is input, the output impedance of the carrier amplifier 21 is twice as high as when a large signal is input. That is, when a small signal is input, the peak amplifier 22 is in the off state, and the output impedance of the carrier amplifier 21 is increased, so that the amplification circuit 10 can operate with high efficiency.

On the other hand, when a large signal is input, the carrier amplifier 21 and the peak amplifier 22 can operate to output a large power signal, and the output impedance of the peak amplifier 22 is low, so that the signal distortion can be suppressed.

### [1.4 Circuit Configuration of High Frequency Circuit 500 According to Comparative Example]

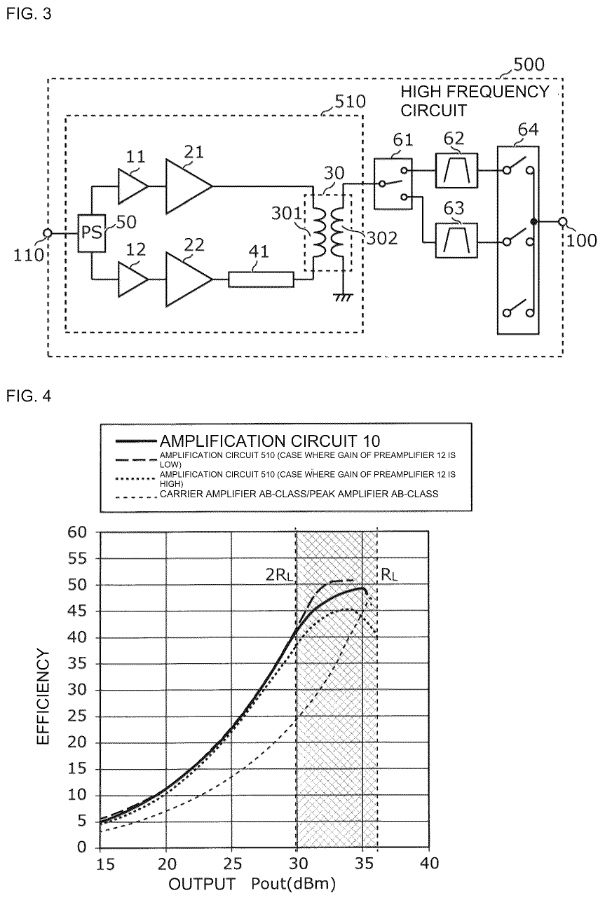

FIG. 3 is a circuit configuration diagram of a high frequency circuit 500 according to a comparative example 1. The high frequency circuit 500 according to the present comparative example is a Doherty amplification circuit in the related art that amplifies the high frequency signal of the band A and the high frequency signal of the band B and transmits the amplified signals. As illustrated in the same drawing, the high frequency circuit 500 includes an amplification circuit 510, filters 62 and 63, switches 61 and 64, the input terminal 110, and an antenna connection terminal 100. The high frequency circuit 500 according to the present comparative example is different from the high frequency circuit 1 according to the exemplary embodiment only in the configuration of the amplification circuit 510. Hereinafter, in the high frequency circuit 500 according to the present comparative example, the amplification circuit 510 different from that of the high frequency circuit 1 according to the exemplary embodiment will be described.

The amplification circuit 510 includes the carrier amplifier 21, the peak amplifier 22, preamplifiers 11 and 12, the phase shift line 41, the transformer 30, and a phase shift circuit 50. The amplification circuit 510 according to the present comparative example is different from the amplification circuit 10 according to the exemplary embodiment in that the preamplifier 12 and the phase shift circuit 50 are added instead of the preamplifier 23. Hereinafter, in the amplification circuit 510 according to the present comparative example, the different configuration from the amplification circuit 10 according to the exemplary embodiment will be mainly described.

The carrier amplifier 21 amplifies the high frequency signal of the band A or the band B input to the carrier amplifier 21. The carrier amplifier 21 is the A-class (or AB-class) amplification circuit that can perform the amplification operation for all of the power levels of the signal input to the carrier amplifier 21, and particularly, can perform a highly efficient amplification operation in the low-output region and a medium-output region.

The peak amplifier 22 amplifies the high frequency signal of the band A or the band B input to the peak amplifier 22. The peak amplifier 22 is the C-class amplification circuit that can perform the amplification operation in the region in which the power level of the signal input to the peak amplifier 22 is high. The peak amplifier 22 can perform the amplification operation with low distortion in the high-output region.

The preamplifier 11 amplifies the high frequency signal of the band A or the band B output from the phase shift circuit 50. The preamplifier 11 is the A-class (or AB-class) amplification circuit that can perform the amplification operation for all of the power levels of the signal input to the preamplifier 11.

The preamplifier 12 amplifies the high frequency signal of the band A or the band B output from the phase shift circuit 50. The preamplifier 12 is a C-class amplification circuit that can perform the amplification operation in a region in which the power level of the signal input to the preamplifier 12 is high. The preamplifier 12 can perform the amplification operation with low distortion in the high-output region.

The phase shift circuit 50 splits the signal output from the input terminal 110 to output the split signal to the preamplifiers 11 and 12. In this case, the phase shift circuit 50 adjusts a phase of the split signal.

The input terminal of the preamplifier 11 is connected to the phase shift circuit 50, and the output terminal of the preamplifier 11 is connected to the input terminal of the carrier amplifier 21. An input terminal of the preamplifier 12 is connected to the phase shift circuit 50, and an output terminal of the preamplifier 12 is connected to the input terminal of the peak amplifier 22. The output terminal of the carrier amplifier 21 is connected to one end of the input side coil 301, and the output terminal of the peak amplifier 22 is connected to one end of the phase shift line 41. The other end of the phase shift line 41 is connected to the other end of the input side coil 301. One end of the output side coil 302 is connected to the antenna connection terminal 100 with the switches 61 and 64 and the filters 62 and 63 interposed therebetween, and the other end of the output side coil 302 is connected to the ground.

The preamplifier 11 is disposed on the input side (preceding stage) of the carrier amplifier 21 and functions as the drive amplifier of the carrier amplifier 21. The preamplifier 12 is disposed on the input side (preceding stage) of the peak amplifier 22 and functions as the drive amplifier of the peak amplifier 22. Since the preamplifier 11 and the preamplifier 12 are not directly connected to each other, the preamplifier 11 and the preamplifier 12 do not operate in conjunction with each other. That is, since the behavior of the output signal is different between the preamplifier 11 and the preamplifier 12, the preamplifier 11 and the preamplifier 12 do not perform a so-called pair operation.

In addition, an amplification transistor included in the preamplifier 12 is not formed in the forming region of the amplification transistor included in the carrier amplifier 21. That is, since the preamplifier 12 and the carrier amplifier 21 do not share the forming region of the amplification transistor, the preamplifier 12 and the carrier amplifier 21 do not perform a so-called pair operation.

In the amplification circuit 510 according to the present comparative example, when a small signal is input, the output impedance of the carrier amplifier 21 is twice as high as when a large signal is input. That is, when a small signal is input, the peak amplifier 22 is in the off state, and the output impedance of the carrier amplifier 21 is increased, so that the amplification circuit 510 can operate with high efficiency. On the other hand, when a large signal is input, the carrier amplifier 21 and the peak amplifier 22 can operate to output a large power signal, and the output impedance of the peak amplifier 22 is low, so that the signal distortion can be suppressed.

### [1.5 Characteristic Comparison Between Amplification Circuit According to Exemplary Embodiment and Comparative Example 1]

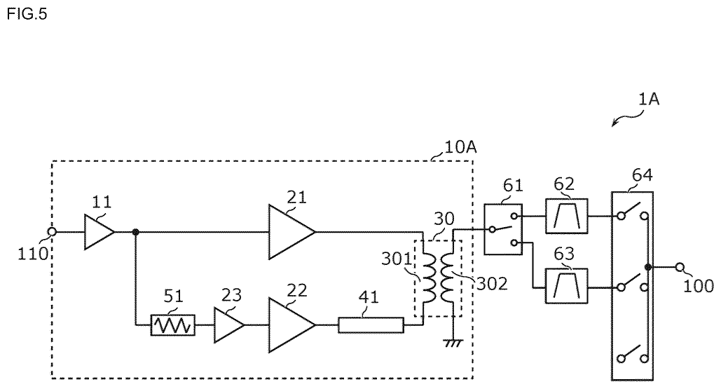

FIG. 4 is a graph illustrating a relationship between output power and the efficiency in the amplification circuits according to the exemplary embodiment and the comparative example 1. In FIG. 4, a horizontal axis represents the power level of the signal output from the amplification circuit 10 or 510, and a vertical axis represents the efficiency (power addition efficiency) of each amplification circuit.

As illustrated in the same drawing, in both the amplification circuits according to the exemplary embodiment and the comparative example 1, the carrier amplifier 21 is saturated at the impedance 2R_{L} at the input power Ps (in FIG. 4, Pout is in the vicinity of 30 dBm). Further, as the input power is increased from Ps (in FIG. 4, Pout is higher than 30 dBm), the impedance of the carrier amplifier 21 is decreased to R_{L}. Simultaneously, the peak amplifier 22 starts to operate at the input power Ps.

Here, in the amplification circuit 510 according to the comparative example 1, in a case in which gain of the preamplifier 12 is relatively high, the peak amplifier 22 starts to operate in a region lower than Ps. Therefore, the efficiency is decreased in the vicinity of the input power Ps (in FIG. 4, Pout is in the vicinity of 30 dBm). Further, in a region in which the input power is higher than Ps, the peak amplifier 22 is oversaturated, so that the efficiency in a region in which the output Pout is maximized (in FIG. 4, Pout is in the vicinity of 35 dBm) is deteriorated.

On the other hand, in the amplification circuit 510 according to the comparative example 1, in a case where the gain of the preamplifier 12 is relatively low, the peak amplifier 22 starts to operate in a region higher than Ps. Therefore, the impedance of the peak amplifier 22 is not lowered to R_{L}, so that the maximum output power is insufficient (in FIG. 4, Pout does not reach 35 dBm).

On the other hand, with the amplification circuit 10 according to the present exemplary embodiment, the preamplifier 23 is connected to the output terminal of the preamplifier 11 that functions as the drive amplifier of the carrier amplifier 21. Therefore, the amplification operation and the behavior of the output signal (output power) of the preamplifier 23 reflect the behavior of the output signal (output power) of the preamplifier 11. That is, since the preamplifier 11 and the preamplifier 23 do not operate individually, and the preamplifier 23 operates in association with the preamplifier 11, the preamplifier 23 can operate to reflect the variation of the preamplifier 11. That is, the preamplifier 23 does not operate independently of the preamplifier 11, but performs the pair operation with the preamplifier 11. Accordingly, since the substantial gain of the preamplifier 23 is linked with that of the preamplifier 11, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient. The substantial gain of the preamplifier 23 is the gain of the peak amplifier 22 as a preamplifier, and is the output power of the preamplifier 23 with respect to the power input to the input terminal 110.

Further, with the amplification circuit 10 according to the present exemplary embodiment, since the preamplifier 23 performs the pair operation with the carrier amplifier 21, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient.

### [1.6 Circuit Configuration of High Frequency Circuit 1A According to Modification Example 1]

FIG. 5 is a circuit configuration diagram of a high frequency circuit 1A according to a modification example 1. As illustrated in the same drawing, the high frequency circuit 1A includes an amplification circuit 10A, the filters 62 and 63, the switches 61 and 64, the input terminal 110, and the antenna connection terminal 100. The high frequency circuit 1A according to the present modification example is different from the high frequency circuit 1 according to the exemplary embodiment only in the configuration of the amplification circuit 10A. Hereinafter, in the high frequency circuit 1A according to the present modification example, the amplification circuit 10A having a different configuration from the high frequency circuit 1 according to the exemplary embodiment will be described.

As illustrated in FIG. 5, the amplification circuit 10A includes the carrier amplifier 21, the peak amplifier 22, the preamplifiers 11 and 23, the phase shift line 41, the transformer 30, and an attenuator 51. The amplification circuit 10A according to the present modification example is different from the amplification circuit 10 according to the exemplary embodiment only in that the attenuator 51 is added. Hereinafter, in the amplification circuit 10A according to the present modification example, the description of the same configuration as the amplification circuit 10 according to the exemplary embodiment will be omitted, and the different configuration will be mainly described.

The attenuator 51 is an example of a first attenuator and is connected between the output terminal of the preamplifier 11 and the input terminal of the preamplifier 23.

The input terminal of the preamplifier 11 is connected to the input terminal 110, and the output terminal of the preamplifier 11 is connected to the input terminal of the carrier amplifier 21 and one end of the attenuator 51. The input terminal of the preamplifier 23 is connected to the other end of the attenuator 51, and the output terminal of the preamplifier 23 is connected to the input terminal of the peak amplifier 22. The output terminal of the carrier amplifier 21 is connected to one end of the input side coil 301, and the output terminal of the peak amplifier 22 is connected to one end of the phase shift line 41. The other end of the phase shift line 41 is connected to the other end of the input side coil 301. One end of the output side coil 302 is connected to the antenna connection terminal 100 with the switches 61 and 64 and the filters 62 and 63 interposed therebetween, and the other end of the output side coil 302 is connected to the ground.

The preamplifier 23 operates in association with the preamplifier 11, but the peak amplifier 22 receives the signals amplified by the preamplifiers 11 and 23, and it is assumed that the power of the signal is excessive. On the other hand, by disposing the attenuator 51 at an input stage of the peak amplifier 22, it is possible to suppress the input of the excessive signal to the peak amplifier 22. In addition, it is possible to suppress the fluctuation in the impedance among the preamplifier 23, the peak amplifier 22, and the carrier amplifier 21. Therefore, it is possible to further suppress the decrease in the efficiency in the vicinity of the input power Ps and the deterioration in the efficiency in the maximum output power region, and it is possible to further prevent the maximum output power from being insufficient.

The attenuator 51 may be connected between the output terminal of the preamplifier 23 and the input terminal of the peak amplifier 22.

### [1.7 Circuit Configuration of High Frequency Circuit 1B According to Modification Example 2]

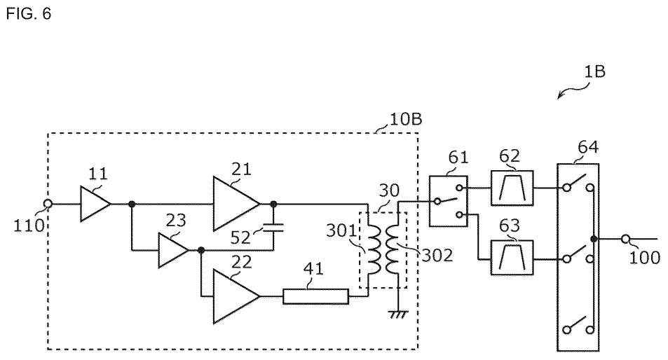

FIG. 6 is a circuit configuration diagram of a high frequency circuit 1B according to a modification example 2. As illustrated in the same drawing, the high frequency circuit 1B includes an amplification circuit 10B, the filters 62 and 63, the switches 61 and 64, the input terminal 110, and the antenna connection terminal 100. The high frequency circuit 1B according to the present modification example is different from the high frequency circuit 1 according to the exemplary embodiment only in the configuration of the amplification circuit 10B. Hereinafter, in the high frequency circuit 1B according to the present modification example, the amplification circuit 10B having a different configuration from the high frequency circuit 1 according to the exemplary embodiment will be described.

As illustrated in FIG. 6, the amplification circuit 10B includes the carrier amplifier 21, the peak amplifier 22, the preamplifiers 11 and 23, the phase shift line 41, the transformer 30, and a capacitor 52. The amplification circuit 10B according to the present modification example is different from the amplification circuit 10 according to the exemplary embodiment only in that the capacitor 52 is added. Hereinafter, in the amplification circuit 10B according to the present modification example, the description of the same configuration as the amplification circuit 10 according to the exemplary embodiment will be omitted, and the different configuration will be mainly described.

The capacitor 52 is disposed in series to a path that connects the output terminal of the carrier amplifier 21 and the output terminal of the preamplifier 23.

The input terminal of the preamplifier 11 is connected to the input terminal 110, and the output terminal of the preamplifier 11 is connected to the input terminal of the carrier amplifier 21 and the input terminal of the preamplifier 23. The output terminal of the preamplifier 23 is connected to the input terminal of the peak amplifier 22 and one end of the capacitor 52. The output terminal of the carrier amplifier 21 is connected to the other end of the capacitor 52 and one end of the input side coil 301, and the output terminal of the peak amplifier 22 is connected to one end of the phase shift line 41. The other end of the phase shift line 41 is connected to the other end of the input side coil 301. One end of the output side coil 302 is connected to the antenna connection terminal 100 with the switches 61 and 64 and the filters 62 and 63 interposed therebetween, and the other end of the output side coil 302 is connected to the ground.

With the above-described configuration, the peak amplifier 22 receives the signal amplified by the preamplifier 23 operating in association with the preamplifier 11. Further, the peak amplifier 22 receives information (output power or the like) of the output signal of the carrier amplifier 21 with the capacitor 52 interposed therebetween.

Accordingly, the behavior of the preamplifier 23 can operate in association with the preamplifier 11, and an operation start timing of the peak amplifier 22 can be controlled based on a timing at which the carrier amplifier 21 is oversaturated. Therefore, it is possible to suppress the decrease in the efficiency in the vicinity of the input power Ps and the deterioration in the efficiency in the maximum output power region with high accuracy, and it is possible to prevent the maximum output power from being insufficient with high accuracy.

### [1.8 Circuit Configuration of High Frequency Circuit 1C According to Modification Example 3]

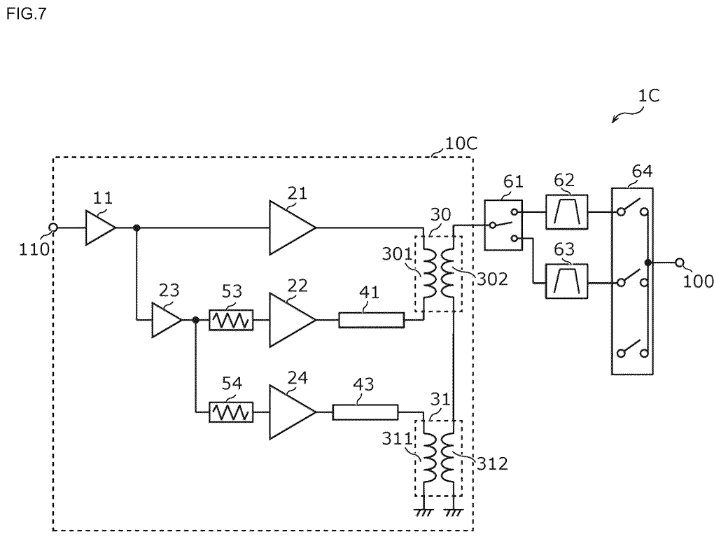

FIG. 7 is a circuit configuration diagram of a high frequency circuit 1C according to a modification example 3. As illustrated in the same drawing, the high frequency circuit 1C includes an amplification circuit 10C, the filters 62 and 63, the switches 61 and 64, the input terminal 110, and the antenna connection terminal 100. The high frequency circuit 1C according to the present modification example is different from the high frequency circuit 1 according to the exemplary embodiment only in the configuration of the amplification circuit 10C. Hereinafter, in the high frequency circuit 1C according to the present modification example, the amplification circuit 10C having a different configuration from the high frequency circuit 1 according to the exemplary embodiment will be described.

As illustrated in FIG. 7, the amplification circuit 10C includes the carrier amplifier 21, peak amplifiers 22 and 24, the preamplifiers 11 and 23, phase shift lines 41 and 43, transformers 30 and 31, and attenuators 53 and 54. The amplification circuit 10C according to the present modification example is different from the amplification circuit 10 according to the exemplary embodiment in that the peak amplifier 24, the attenuators 53 and 54, and the transformer 31 are added. Hereinafter, in the amplification circuit 10C according to the present modification example, the description of the same configuration as the amplification circuit 10 according to the exemplary embodiment will be omitted, and the different configuration will be mainly described.

The carrier amplifier 21 is an example of a first amplifier according to the present modification example and amplifies the high frequency signal of the band A or the band B input to the carrier amplifier 21. The carrier amplifier 21 is, for example, the A-class (or AB-class) amplification circuit that can perform the amplification operation for all of the power levels of the signal input to the carrier amplifier 21, and particularly, can perform a highly efficient amplification operation in the low-output region and the medium-output region.

The peak amplifier 22 is an example of a third amplifier according to the present modification example and amplifies the high frequency signal of the band A or the band B input to the peak amplifier 22. The peak amplifier 22 is, for example, the C-class amplification circuit that can perform the amplification operation in the region in which the power level of the signal input to the peak amplifier 22 is high. Since a bias voltage lower than the bias voltage applied to the amplification transistor included in the carrier amplifier 21 is applied to the amplification transistor included in the peak amplifier 22, the output impedance is lower as the power level of the signal input to the peak amplifier 22 is higher. As a result, the peak amplifier 22 can perform the amplification operation with low distortion in the medium-output region and the high-output region.

The peak amplifier 24 is an example of a fifth amplifier according to the present exemplary embodiment and amplifies the high frequency signal of the band A or the band B input to the peak amplifier 24. The peak amplifier 24 is, for example, a C-class amplification circuit that can perform the amplification operation in a region in which the power level of the signal input to the peak amplifier 24 is high. Since a bias voltage lower than the bias voltage applied to the amplification transistor included in the carrier amplifier 21 is applied to the amplification transistor included in the peak amplifier 24, the output impedance is lower as the power level of the signal input to the peak amplifier 24 is higher. As a result, the peak amplifier 24 can perform the amplification operation with low distortion in the high-output region.

The attenuator 53 is an example of a first attenuator and is connected between the output terminal of the preamplifier 23 and the input terminal of the peak amplifier 22. The attenuator 54 is an example of a second attenuator and is connected between a connecting point of the output terminal of the preamplifier 23 and the input terminal of the peak amplifier 22, and an input terminal of the peak amplifier 24.

At least one of the attenuators 53 and 54 may be omitted.

The phase shift line 43 is an example of a second phase shift circuit, and is, for example, a ¼ wavelength transmission line. The phase shift line 43 delays the phase of the high frequency signal input from one end thereof by a ¼ wavelength and outputs the high frequency signal from the other end thereof. The second phase shift circuit need not have a form of the phase shift line 43, and may be, for example, a circuit configured with chip-shaped inductor and capacitor.

The transformer 30 is an example of a first transformer and has the input side coil 301 and the output side coil 302. The transformer 31 is an example of a second transformer and has an input side coil 311 (second input side coil) and an output side coil 312 (second output side coil).

The input terminal of the preamplifier 11 is connected to the input terminal 110, and the output terminal of the preamplifier 11 is connected to the input terminal of the carrier amplifier 21 and the input terminal of the preamplifier 23. The output terminal of the preamplifier 23 is connected to one end of the attenuator 53 and one end of the attenuator 54. The output terminal of the carrier amplifier 21 is connected to one end of the input side coil 301. The input terminal of the peak amplifier 22 is connected to the other end of the attenuator 53, and the output terminal of the peak amplifier 22 is connected to one end of the phase shift line 41. The other end of the phase shift line 41 is connected to the other end of the input side coil 301. The input terminal of the peak amplifier 24 is connected to the other end of the attenuator 54, and an output terminal of the peak amplifier 24 is connected to one end of the phase shift line 43. The other end of the phase shift line 43 is connected to one end of the input side coil 311. One end of the output side coil 302 is connected to the antenna connection terminal 100 with the switches 61 and 64 and the filters 62 and 63 interposed therebetween, and the other end of the output side coil 302 is connected to one end of the output side coil 312. The other end of the input side coil 311 and the other end of the output side coil 312 are connected to the ground.

The preamplifier 23 is disposed on an input side (preceding stage) of the peak amplifiers 22 and 24 and functions as drive amplifiers of the peak amplifiers 22 and 24, but is connected to the output terminal of the preamplifier 11 that functions as the drive amplifier of the carrier amplifier 21. Therefore, the amplification operation and the behavior of the output signal of the preamplifier 23 reflect the behavior of the output signal of the preamplifier 11. That is, it can be said that the preamplifier 11 and the preamplifier 23 perform a so-called pair operation from the viewpoint that the behavior of the output signal is the same.

The amplification transistor included in the preamplifier 23 may be formed in the forming region of the amplification transistor included in the carrier amplifier 21. That is, it can be said that the preamplifier 23 and the carrier amplifier 21 perform a so-called pair operation from the viewpoint that the forming regions of the amplification transistors are shared.

Here, the operation of the amplification circuit 10C will be described.

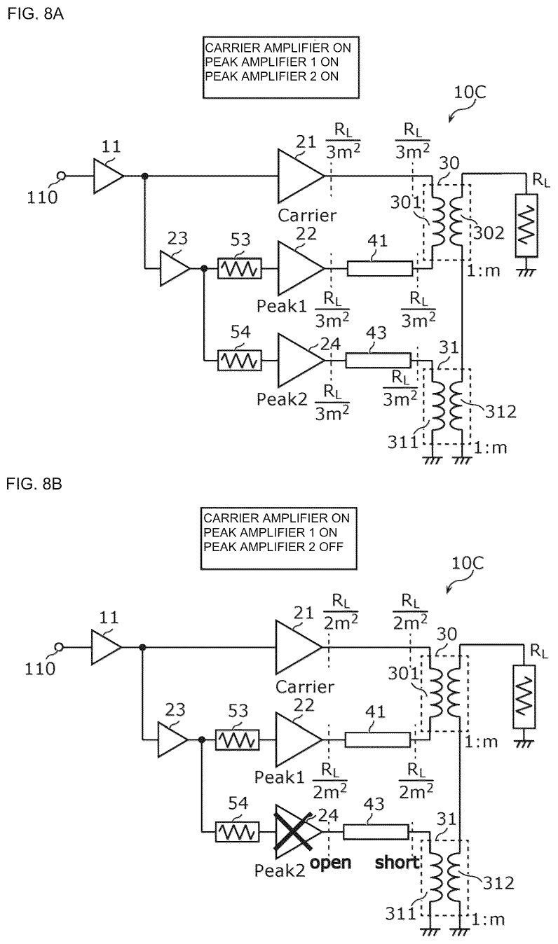

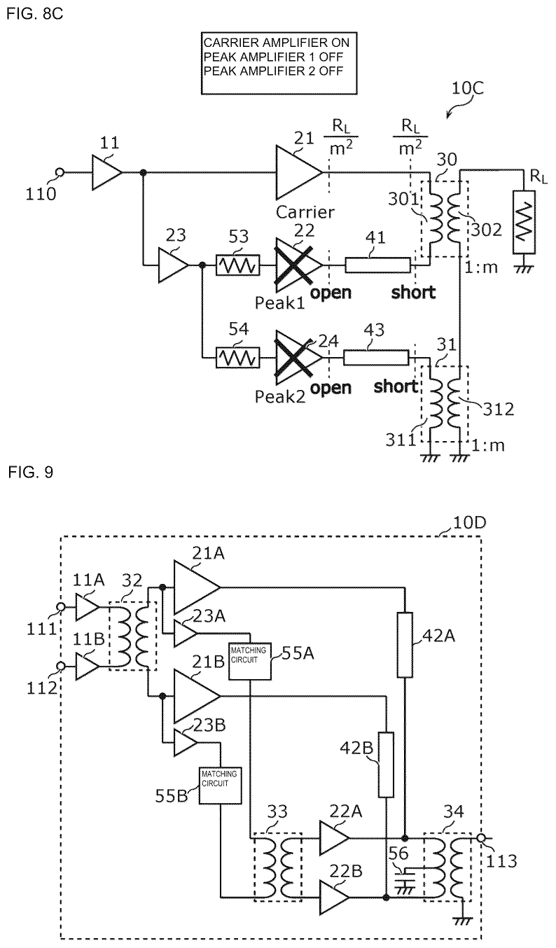

FIG. 8A is a circuit state diagram of the amplification circuit 10C according to the modification example 3 when a large signal is input. FIG. 8B is a circuit state diagram of the amplification circuit 10C according to the modification example 3 when a medium signal is input. FIG. 8C is a circuit state diagram of the amplification circuit 10C according to the modification example 3 when a small signal is input.

First, as illustrated in FIG. 8A, in a case where the carrier amplifier 21 and the peak amplifiers 22 and 24 operate (ON) (when a large signal is input), the output impedances when the load side is seen from the output terminals of the carrier amplifier 21 and the peak amplifiers 22 and 24 are each represented by R_{L}/3m². The transformers 30 and 31 each perform transformation at a ratio of 1:m. In addition, an impedance of a load connected to one end of the output side coil 302 is R_{L}.

Next, as illustrated in FIG. 8B, in a case where the carrier amplifier 21 and the peak amplifier 22 operate (ON) and the peak amplifier 24 does not operate (OFF) (when a medium signal is input), the output impedances when the load side is seen from the output terminals of the carrier amplifier 21 and the peak amplifier 22 are each represented by R_{L}/2m². In this case, the output impedance when the load side is seen from the output terminal of the peak amplifier 24 is in the open state.

Next, as illustrated in FIG. 8C, in a case where the carrier amplifier 21 operates (ON) and the peak amplifiers 22 and 24 do not operate (OFF) (when a small signal is input), the output impedance when the load side is seen from the output terminal of the carrier amplifier 21 is represented by R_{L}/m². In this case, the output impedances when the load side is seen from the output terminals of the respective peak amplifiers 22 and 24 are in the open state.

As described above, when a small signal is input, the output impedance of the carrier amplifier 21 is three times as high as when a large signal is input. That is, when a small signal is input, the peak amplifiers 22 and 24 are in the off state, and the output impedance of the carrier amplifier 21 is increased, so that the amplification circuit 10C can operate with high efficiency. In addition, when a medium signal is input, the output impedance of the carrier amplifier 21 is twice as high as when a large signal is input, and the output impedance of the peak amplifier 22 is the same as the output impedance of the carrier amplifier 21. In addition, when a large signal is input, the carrier amplifier 21 and the peak amplifiers 22 and 24 can operate to output a large power signal, and the output impedances of the peak amplifiers 22 and 24 are low, so that the signal distortion can be suppressed.

With the high frequency circuit 1C according to the present modification example, since the three amplifiers such as the carrier amplifier 21 and the peak amplifiers 22 and 24 are provided, a back-off amount, which is a difference in power from the high-output region in which the carrier amplifier 21 and the peak amplifiers 22 and 24 are in the on state to the low-output region in which only the carrier amplifier 21 is in the on state, can be secured in a stepwise and large manner.

In addition, since the substantial gain of the preamplifier 23 is linked with that of the preamplifier 11, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient. Further, since the preamplifier 23 performs the pair operation with the carrier amplifier 21, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient.

### [1.9 Circuit Configuration of Amplification Circuit 10D According to Modification Example 4]

FIG. 9 is a circuit configuration diagram of an amplification circuit 10D according to a modification example 4. As illustrated in the same drawing, the amplification circuit 10D includes carrier amplifiers 21A and 21B, peak amplifiers 22A and 22B, preamplifiers 11A, 11B, 23A, and 23B, phase shift lines 42A and 42B, transformers 32, 33, and 34, matching circuits 55A and 55B, and a capacitor 56. The amplification circuit 10 according to the exemplary embodiment is the voltage-combining type Doherty amplification circuit, whereas the amplification circuit 10D according to the present modification example is a current-combining type Doherty amplification circuit.

The carrier amplifier 21A amplifies the high frequency signal of the band A or the band B input to the carrier amplifier 21A. The carrier amplifier 21B amplifies the high frequency signal of the band A or the band B input to the carrier amplifier 21B. The carrier amplifiers 21A and 21B are, for example, A-class (or AB-class) amplification circuits that can perform an amplification operation for all of the power levels of the signals input to the carrier amplifiers 21A and 21B are, and particularly, can perform a highly efficient amplification operation in the low-output region and a medium-output region. The carrier amplifiers 21A and 21B constitute a first amplifier according to the present modification example.

The peak amplifier 22A amplifies the high frequency signal of the band A or the band B input to the peak amplifier 22A. The peak amplifier 22B amplifies the high frequency signal of the band A or the band B input to the peak amplifier 22B. The peak amplifiers 22A and 22B are, for example, C-class amplification circuits that can perform an amplification operation in a region in which the power level of the signal input to the peak amplifier 22B is high. Since a bias voltage lower than the bias voltage applied to each amplification transistor included in the carrier amplifiers 21A and 21B is applied to each amplification transistor included in the peak amplifiers 22A and 22B, the output impedance is lower as the power levels of the signals input to the peak amplifiers 22A and 22B are higher. As a result, the peak amplifiers 22A and 22B can perform the amplification operation with low distortion in the high-output region. The peak amplifiers 22A and 22B constitute a third amplifier according to the present modification example.

The preamplifier 11A amplifies the high frequency signal of the band A or the band B input from an input terminal 111 (signal input terminal). The preamplifier 11B amplifies the high frequency signal of the band A or the band B input from an input terminal 112 (signal input terminal). The preamplifiers 11A and 11B are, for example, A-class (or AB-class) amplification circuits that can perform an amplification operation for all of the power levels of the signals input to the preamplifiers 11A and 11B. For example, a bias voltage higher than the bias voltage applied to each amplification transistor included in the peak amplifiers 22A and 22B is applied to each amplification transistor included in the preamplifiers 11A and 11B. The preamplifiers 11A and 11B constitute a fourth amplifier according to the present modification example.

An input terminal of the preamplifier 11A is connected to the input terminal 111, and an input terminal of the preamplifier 11B is connected to the input terminal 112.

The preamplifier 23A amplifies the high frequency signal of the band A or the band B input to the preamplifier 23A. The preamplifier 23B amplifies the high frequency signal of the band A or the band B input to the preamplifier 23B. The preamplifiers 23A and 23B are, for example, A-class (or AB-class) amplification circuits that can perform an amplification operation for all of the power levels of the signals input to the preamplifiers 23A and 23B. For example, a bias voltage higher than the bias voltage applied to each amplification transistor included in the peak amplifiers 22A and 22B is applied to each amplification transistor included in the preamplifiers 23A and 23B. The preamplifiers 23A and 23B constitute a second amplifier according to the present modification example.

The transformer 32 has a primary side coil and a secondary side coil. One end of the primary side coil of the transformer 32 is connected to an output terminal of the preamplifier 11A, and the other end of the primary side coil is connected to an output terminal of the preamplifier 11B. One end of the secondary side coil of the transformer 32 is connected to an input terminal of the carrier amplifier 21A and an input terminal of the preamplifier 23A, and the other end of the secondary side coil is connected to an input terminal of the carrier amplifier 21B and an input terminal of the preamplifier 23B. The transformer 32 performs the impedance matching among the preamplifiers 11A and 11B, the carrier amplifiers 21A and 21B, and the preamplifiers 23A and 23B.

The transformer 33 has a primary side coil and a secondary side coil. One end of the primary side coil of the transformer 33 is connected to an output terminal of the preamplifier 23A with the matching circuit 55A interposed therebetween, and the other end of the primary side coil is connected to an output terminal of the preamplifier 23B with the matching circuit 55B interposed therebetween. One end of the secondary side coil of the transformer 33 is connected to an input terminal of the peak amplifier 22A, and the other end of the secondary side coil is connected to an input terminal of the peak amplifier 22B. The transformer 33 performs the impedance matching between the preamplifiers 23A and 23B and the peak amplifiers 22A and 22B.

The transformer 34 has a primary side coil and a secondary side coil. One end of the primary side coil of the transformer 34 is connected to the other end of the phase shift line 42A and an output terminal of the peak amplifier 22A, and the other end of the primary side coil is connected to the other end of the phase shift line 42B and an output terminal of the peak amplifier 22B. One end of the secondary side coil of the transformer 34 is connected to an output terminal 113 (signal output terminal), and the other end of the secondary side coil is connected to the ground. The transformer 34 transforms a balanced signal (differential signal) into an unbalanced signal.

The phase shift line 42A is an example of a phase shift circuit, and is, for example, a ¼ wavelength transmission line. The phase shift line 42A delays the phase of the high frequency signal input from one end thereof by a ¼ wavelength and outputs the high frequency signal from the other end thereof. One end of the phase shift line 42A is connected to an output terminal of the carrier amplifier 21A, and the other end of the phase shift line 42A is connected to the output terminal of the peak amplifier 22A and one end of the primary side coil of the transformer 34. The phase shift line 42B is an example of a phase shift circuit, and is, for example, a ¼ wavelength transmission line. The phase shift line 42B delays the phase of the high frequency signal input from one end thereof by a ¼ wavelength and outputs the high frequency signal from the other end thereof. One end of the phase shift line 42B is connected to an output terminal of the carrier amplifier 21B, and the other end of the phase shift line 42B is connected to the output terminal of the peak amplifier 22B and the other end of the primary side coil of the transformer 34.

One end (one electrode) of the capacitor 56 is connected to the vicinity of an intermediate point of the primary side coil of the transformer 34, and the other end (the other electrode) is connected to the ground. With the capacitor 56, common mode noise generated between the carrier amplifier 21A and the carrier amplifier 21B, and common mode noise generated between the peak amplifier 22A and the peak amplifier 22B can be reduced.

With the above-described configuration, the differential signals input from the input terminals 111 and 112 are amplified by the preamplifiers 11A and 11B and the carrier amplifiers 21A and 21B, and the balanced signals (differential signals) input from the input terminals 111 and 112 are amplified by the preamplifiers 11A and 11B, the preamplifiers 23A and 23B, and the peak amplifiers 22A and 22B. The balanced signals (differential signals) amplified by the carrier amplifiers 21A and 21B and the balanced signals (differential signals) amplified by the peak amplifiers 22A and 22B are current-combined, transformed into the unbalanced signals by the transformer 34, and output from the output terminal 113.

In the amplification circuit 10D according to the present modification example, the transformers 32 and 33, the matching circuits 55A and 55B, and the capacitor 56 need not be provided.

The preamplifier 23A is disposed on an input side (preceding stage) of the peak amplifier 22A and functions as a drive amplifier of the peak amplifier 22A, but is connected to the output terminals of the preamplifiers 11A and 11B that function as drive amplifiers of the carrier amplifier 21A. In addition, the preamplifier 23B is disposed on an input side (preceding stage) of the peak amplifier 22B and functions as a drive amplifier of the peak amplifier 22B, but is connected to the output terminals of the preamplifiers 11A and 11B that function as drive amplifiers of the carrier amplifier 21B. Therefore, the amplification operations and the behavior of the output signals of the preamplifiers 23A and 23B reflect the behavior of the output signals of the preamplifiers 11A and 11B. That is, it can be said that the preamplifiers 11A and 11B and the preamplifiers 23A and 23B perform a so-called pair operation from the viewpoint that the behavior of the output signals is the same.

The amplification transistors included in the preamplifiers 23A and 23B may be formed in the forming region of the amplification transistors included in the carrier amplifiers 21A and 21B. Accordingly, it can be said that the preamplifiers 23A and 23B and the carrier amplifiers 21A and 21B perform a so-called pair operation from the viewpoint that the forming regions of the amplification transistors are shared.

Accordingly, since the substantial gain of the preamplifiers 23A and 23B is linked with that of the preamplifiers 11A and 11B, it is possible to prevent the substantial gain of the preamplifiers 23A and 23B from being relatively increased alone, and it is possible to suppress the decrease in the efficiency in the vicinity of the input power Ps and the deterioration in the efficiency in the maximum output power region. In addition, it is possible to prevent the substantial gain of the preamplifiers 23A and 23B from being relatively decreased alone, and it is possible to prevent the maximum output power from being insufficient.

Further, with the amplification circuit 10D according to the present modification example, since the preamplifiers 23A and 23B perform the pair operation with the carrier amplifiers 21A and 21B, it is possible to prevent the substantial gain of the preamplifiers 23A and 23B from being relatively increased alone, and it is possible to suppress the decrease in the efficiency in the vicinity of the input power Ps and the deterioration in the efficiency in the maximum output power region. In addition, it is possible to prevent the substantial gain of the preamplifiers 23A and 23B from being relatively decreased alone, and it is possible to prevent the maximum output power from being insufficient.

In the present modification example, the example has been described in which a current-combining type Doherty amplification circuit is realized by a differential amplification circuit, but the current-combining type Doherty amplification circuit according to the present modification example need not be the differential amplification circuit. That is, for example, the amplification circuit 10D need only include the carrier amplifier 21A, the peak amplifier 22A, the preamplifiers 11A and 23A, and the phase shift line 42A, in which the input terminal of the preamplifier 11A is connected to the input terminal 111, the output terminal of the preamplifier 11A is connected to the input terminal of the carrier amplifier 21A and the input terminal of the preamplifier 23A, the output terminal of the preamplifier 23A is connected to the input terminal of the peak amplifier 22A, the output terminal of the carrier amplifier 21A is connected to one end of the phase shift line 42A, and the output terminal of the peak amplifier 22A is connected to the other end of the phase shift line 42A.

Accordingly, it is possible to prevent the substantial gain of the preamplifier 23A from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23A from being relatively decreased alone, and it is possible to prevent the maximum output power from being insufficient.

The high frequency circuit according to the modification example 4 is a high frequency circuit having a Doherty amplifier, the high frequency circuit including the carrier amplifiers 21A and 21B that amplify the first high frequency signal to output the first amplified signal, the preamplifiers 23A and 23B that amplify the first high frequency signal to output the second amplified signal, the peak amplifiers 22A and 22B that amplify the second amplified signal to output the third amplified signal, and the combining circuit that combines the first amplified signal and the third amplified signal to output the combined signal. The combining circuit is the phase shift lines 42A and 42B.

### [1.10 Circuit Configuration and Mounting Configuration of Amplification Circuit 10E According to Modification Example 5]

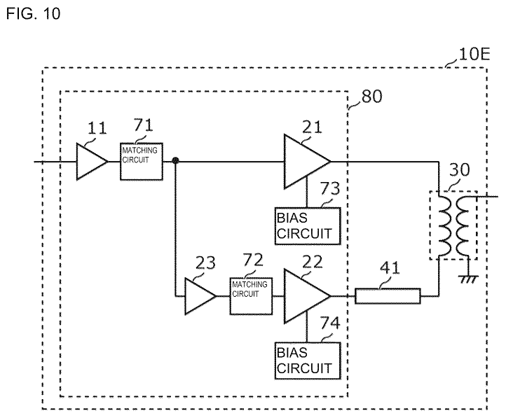

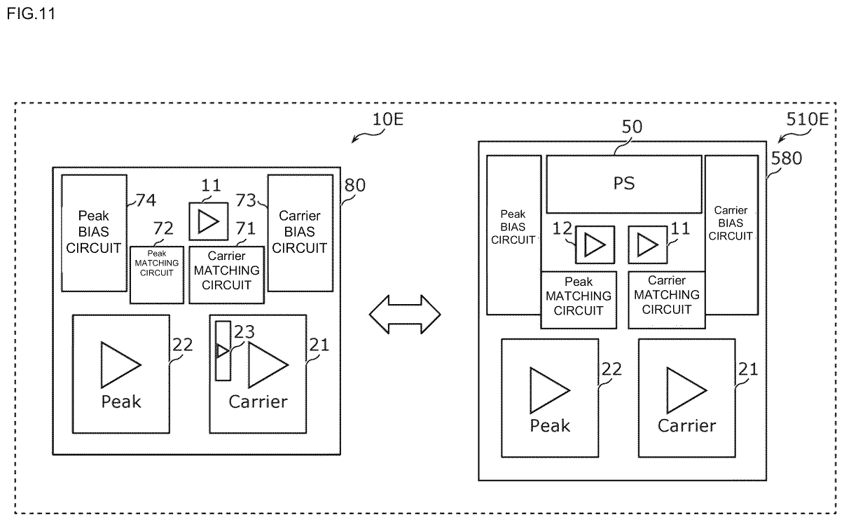

FIG. 10 is a circuit configuration diagram of an amplification circuit 10E according to a modification example 5. The amplification circuit 10E includes the carrier amplifier 21, the peak amplifier 22, the preamplifiers 11 and 23, matching circuits 71 and 72, bias circuits 73 and 74, the phase shift line 41, and the transformer 30. The amplification circuit 10E according to the present modification example is different from the amplification circuit 10 according to the exemplary embodiment in that the matching circuits 71 and 72 and the bias circuits 73 and 74 are added. Hereinafter, in the amplification circuit 10E according to the present modification example, the description of the same configuration as the amplification circuit 10 according to the exemplary embodiment will be omitted, and the different configuration will be mainly described.

The matching circuit 71 is an example of a first matching circuit, and is connected between the output terminal of the preamplifier 11 and a connecting point between the input terminal of the carrier amplifier 21 and the input terminal of the preamplifier 23. The matching circuit 71 performs the impedance matching between the preamplifier 11 and the carrier amplifier 21, and also performs the impedance matching between the preamplifier 11 and the preamplifier 23. The carrier amplifier 21 and the preamplifier 23 are commonly connected to the preamplifier 11, so that the carrier amplifier 21 and the preamplifier 23 are impedance-matched by using the common matching circuit 71. Therefore, the amplification circuit 10E can be reduced in size, and the preamplifier 23 and the carrier amplifier 21 can operate in association with each other.

The matching circuit 72 is an example of a second matching circuit and is connected between the output terminal of the preamplifier 23 and the input terminal of the peak amplifier 22. The matching circuit 72 performs the impedance matching between the preamplifier 23 and the peak amplifier 22.

The bias circuit 73 is a circuit that supplies the bias current (voltage) to the amplification transistor of the carrier amplifier 21. The bias circuit 74 is a circuit that supplies the bias current (voltage) to the amplification transistor of the peak amplifier 22.

The output terminal of the preamplifier 11 is connected to the input terminal of the carrier amplifier 21 and the input terminal of the preamplifier 23 with the matching circuit 71 interposed therebetween. The output terminal of the preamplifier 23 is connected to the input terminal of the peak amplifier 22 with the matching circuit 72 interposed therebetween.

The carrier amplifier 21, the peak amplifier 22, the preamplifiers 11 and 23, the matching circuits 71 and 72, and the bias circuits 73 and 74 may be included in a semiconductor IC 80. The semiconductor IC 80 is configured with, for example, a complementary metal oxide semiconductor (CMOS), and specifically, may be manufactured by a silicon on insulator (SOI) process. In addition, each semiconductor IC 80 may be configured with at least one of GaAs, SiGe, and GaN. The semiconductor material of the semiconductor IC 80 is not limited to the above-described materials.

FIG. 11 is a plan view of the amplification circuit 10E according to the modification example 5 and an amplification circuit 510E according to a comparative example 2. The left side in the same drawing illustrates the disposition of each circuit and each component in a case where a main surface of the semiconductor IC 80 included in the amplification circuit 10E is seen in plan view (perspective view). The right side in the same drawing illustrates the disposition of each circuit and each component in a case where the main surface of a semiconductor IC 580 included in the amplification circuit 510E is seen in plan view (perspective view).

The configuration of the amplification circuit 510E according to the comparative example 2 will be described. The amplification circuit 510E according to the comparative example 2 includes the carrier amplifier 21, the peak amplifier 22, the preamplifiers 11 and 12, the phase shift line 41, the transformer 30, the phase shift circuit 50, a carrier matching circuit, a peak matching circuit, a carrier bias circuit, and a peak bias circuit. The amplification circuit 510E according to the present comparative example is different from the amplification circuit 510 according to Comparative Example 1 illustrated in FIG. 3 in that the carrier matching circuit, the peak matching circuit, the carrier bias circuit, and the peak bias circuit are added. Hereinafter, in the amplification circuit 510E according to the present comparative example, the different configuration from the amplification circuit 510 according to the comparative example 1 will be mainly described.

The carrier matching circuit is connected between the output terminal of the preamplifier 11 and the input terminal of the carrier amplifier 21. The peak matching circuit is connected between the output terminal of the preamplifier 12 and the input terminal of the peak amplifier 22.

The carrier bias circuit supplies the bias current (voltage) to the amplification transistor of the carrier amplifier 21. The peak bias circuit supplies the bias current (voltage) to the amplification transistor of the peak amplifier 22.

The carrier amplifier 21, the peak amplifier 22, the preamplifiers 11 and 12, the carrier matching circuit, the peak matching circuit, the carrier bias circuit, and the peak bias circuit are included in the semiconductor IC 580.

In the amplification circuit 10E illustrated in FIG. 11, the phase shift line 41 and the transformer 30 are not illustrated, but may be included in the semiconductor IC 80 or may be disposed outside the semiconductor IC 80. In the amplification circuit 510E illustrated in FIG. 11, the phase shift line 41 and the transformer 30 are not illustrated, but may be included in the semiconductor IC 580 or may be disposed outside the semiconductor IC 580.

In the amplification circuit 10E illustrated in FIG. 11, the preamplifier 23 is disposed in the forming region of the carrier amplifier 21. Specifically, the amplification transistor included in the preamplifier 23 is formed in the forming region of the amplification transistor included in the carrier amplifier 21. In a case where the amplification transistors included in the preamplifier 23 and the carrier amplifier 21 are the bipolar transistors, for example, an emitter constituting the amplification transistor included in the preamplifier 23 may share at least a part of an emitter constituting the amplification transistor included in the carrier amplifier 21. Accordingly, since the preamplifier 23 and the carrier amplifier 21 share the forming region of the amplification transistor, the preamplifier 23 and the carrier amplifier 21 perform a so-called pair operation.

In a case in which the mounting configurations of the amplification circuits 10E and 510E illustrated in FIG. 11 are compared, in the amplification circuit 10E, the preamplifier 23 is formed in the forming region of the carrier amplifier 21, so that the semiconductor IC 80 can be reduced in size as compared with the amplification circuit 510E in which the preamplifier 12 is formed separately from the other amplifiers.

Since the preamplifier 23 and the carrier amplifier 21 perform the pair operation, the amplification operation and the behavior of the output signal of the preamplifier 23 reflect the amplification operation and the behavior of the output signal of the carrier amplifier 21. As a result, the matching circuit disposed at an input stage of the preamplifier 23 and the matching circuit disposed at an input stage of the carrier amplifier 21 can be shared by one matching circuit 71.

The preamplifier 23 may be disposed adjacent to the carrier amplifier 21. Accordingly, since both the wiring that connects the matching circuit 71 and the preamplifier 23 and the wiring that connects the matching circuit 71 and the carrier amplifier 21 can be shortened, the signal transmission loss can be reduced.

Further, since the preamplifier 23 is connected to the peak amplifier 22, it is desirable that the preamplifier 23 is disposed between the carrier amplifier 21 and the peak amplifier 22.

Accordingly, the wirings that connect the preamplifier 23 and the matching circuit 71 to the peak amplifier 22 can be further shortened, so that the operation start timing of the peak amplifier 22 can be controlled with high accuracy based on the timing at which the carrier amplifier 21 is oversaturated.

In addition, in the case where the main surface of the semiconductor IC 80 is seen in plan view (perspective view), it is desirable that a size of the amplification transistor constituting the preamplifier 23 is smaller than a size of the amplification transistor constituting the carrier amplifier 21 and smaller than a size of the amplification transistor constituting the preamplifier 11.

Accordingly, the gain of the preamplifier 23 can be set to be smaller than the gain of the preamplifier 11 and the gain of the carrier amplifier 21, and thus the peak amplifier 22 can be prevented from starting to operate in the region lower than Ps.

The size of the amplification transistor constituting each of the amplifiers is defined as an area of the forming region of the amplification transistor included in the amplifier in a case where the main surface of the semiconductor IC in which the amplifier is disposed is seen in plan view (perspective view). The size of the amplification transistor constituting each of the amplifiers depends on the number of stages of transistor elements constituting the amplification transistor, the number of cells, or the number of fingers. Therefore, the fact that the size of the amplification transistor is large indicates that a state in which at least one of the fact that the number of stages of the transistor element is large and the fact that the number of cells or the number of fingers is large is satisfied.

In addition, the “sizes of the amplification transistors constituting two amplifiers are equal to each other” includes that the sizes of the amplification transistors constituting the two amplifiers are substantially equal to each other in addition to a case where the sizes of the amplification transistors constituting the two amplifiers strictly match each other. Here, the size of the amplification transistor constituting the amplifier is represented by an area (scale of a range of a two-dimensional region). The fact that the sizes of the respective amplification transistors constituting the two amplifiers are substantially equal to each other indicates that a ratio of a differential value of the sizes of the respective amplification transistors constituting the two amplifiers to a larger size of the sizes of the respective amplification transistors constituting the two amplifiers is 10% or less.

The area of the forming region of the amplification transistor can be measured by recognizing regions of N-type and P-type semiconductors in an image of the amplification transistor captured by irradiating the main surface of the semiconductor IC with X-rays in a normal direction.

In addition, each amplification transistor constituting each amplifier may have a configuration in which a plurality of transistor elements are connected parallel to each other. In this case, in a case in which each of the plurality of transistor elements is a common-emitter type bipolar transistor, the number of amplification transistors is determined by the number of collector terminals. That is, the number of amplification transistors and the number of collector terminals correspond to each other on a one-to-one basis.

As described above, the high frequency circuit 1 according to the present exemplary embodiment includes: the input terminal 110 and the antenna connection terminal 100; the carrier amplifier 21, the peak amplifier 22, the preamplifiers 11 and 23; the transformer 30 having the input side coil 301 and the output side coil 302; and the phase shift line 41, in which the input terminal of the preamplifier 11 is connected to the input terminal 110, the output terminal of the preamplifier 11 is connected to the input terminal of the carrier amplifier 21 and the input terminal of the preamplifier 23, the output terminal of the preamplifier 23 is connected to the input terminal of the peak amplifier 22, the output terminal of the carrier amplifier 21 is connected to one end of the input side coil 301, the output terminal of the peak amplifier 22 is connected to one end of the phase shift line 41, the other end of the phase shift line 41 is connected to the other end of the input side coil 301, and one end of the output side coil 302 is connected to the antenna connection terminal 100.

Accordingly, the preamplifier 23 does not operate independently of the preamplifier 11, but performs the pair operation with the preamplifier 11. Accordingly, since the substantial gain of the preamplifier 23 is linked with that of the preamplifier 11, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient.

In addition, for example, the high frequency circuit 1A according to the modification example 1 may further include the attenuator 51 connected between the output terminal of the preamplifier 11 and the input terminal of the peak amplifier 22.

Accordingly, by disposing the attenuator 51 at the input stage of the peak amplifier 22, it is possible to suppress the input of the excessive signal to the peak amplifier 22. In addition, it is possible to suppress the fluctuation in the impedance among the preamplifier 23, the peak amplifier 22, and the carrier amplifier 21. Therefore, it is possible to further suppress the decrease in the efficiency in the vicinity of the input power Ps and the deterioration in the efficiency in the maximum output power region, and it is possible to further prevent the maximum output power from being insufficient.

In addition, for example, the high frequency circuit 1B according to the modification example 2 may further include the capacitor 52 disposed in series to the path that connects the output terminal of the carrier amplifier 21 and the output terminal of the preamplifier 23.

Accordingly, the behavior of the preamplifier 23 can operate in association with the preamplifier 11, and an operation start timing of the peak amplifier 22 can be controlled based on a timing at which the carrier amplifier 21 is oversaturated. Therefore, it is possible to suppress the decrease in the efficiency in the vicinity of the input power Ps and the deterioration in the efficiency in the maximum output power region with high accuracy, and it is possible to prevent the maximum output power from being insufficient with high accuracy.

In addition, for example, the high frequency circuit according to the modification example 5 may further include the matching circuit 71 connected between the output terminal of the preamplifier 11 and the connecting point between the input terminal of the carrier amplifier 21 and the input terminal of the preamplifier 23.

Accordingly, since the carrier amplifier 21 and the preamplifier 23 are commonly connected to the preamplifier 11, the impedance matching can be performed by using the common matching circuit 71. Therefore, the amplification circuit 10E can be reduced in size, and the preamplifier 23 and the carrier amplifier 21 can operate in association with each other.

In addition, for example, the high frequency circuit according to the modification example 5 may further include the matching circuit 72 connected between the output terminal of the preamplifier 23 and the input terminal of the peak amplifier 22.

Accordingly, the signal power input to the peak amplifier 22 can be controlled with high accuracy, and thus the operation start timing of the peak amplifier 22 can be controlled with high accuracy based on the timing at which the carrier amplifier 21 is oversaturated.

In addition, for example, in the high frequency circuit according to the modification example 5, the carrier amplifier 21, the peak amplifier 22, and the preamplifiers 11 and 23 may be included in the semiconductor IC 80, and in a case where the main surface of the semiconductor IC 80 is seen in plan view, the preamplifier 23 may be disposed between the carrier amplifier 21 and the peak amplifier 22.

As a result, the wiring that connects the preamplifier 23 and the peak amplifier 22 and the wiring that connects the preamplifier 23 and the carrier amplifier 21 can be shortened, and thus the operation start timing of the peak amplifier 22 can be controlled with high accuracy based on the timing at which the carrier amplifier 21 is oversaturated.

In addition, for example, in the high frequency circuit according to the modification example 5, in the case where the main surface of the semiconductor IC 80 is seen in plan view, the size of the amplification transistor constituting the preamplifier 23 may be smaller than the size of the amplification transistor constituting the carrier amplifier 21 and smaller than the size of the amplification transistor constituting the preamplifier 11.

Accordingly, the gain of the preamplifier 23 can be set to be smaller than the gain of the preamplifier 11 and the gain of the carrier amplifier 21, and thus the peak amplifier 22 can be prevented from starting to operate in the region lower than Ps.

In addition, for example, the high frequency circuit 1C according to the modification example 3 may include: the input terminal 110 and the antenna connection terminal 100; the carrier amplifier 21, the peak amplifiers 22 and 24, the preamplifiers 11 and 23; the transformer 30 having the input side coil 301 and the output side coil 302; the transformer 31 having the input side coil 311 and the output side coil 312; and the phase shift lines 41 and 43, in which the input terminal of the preamplifier 11 is connected to the input terminal 110, the output terminal of the preamplifier 11 is connected to the input terminal of the carrier amplifier 21 and the input terminal of the preamplifier 23, the output terminal of the preamplifier 23 is connected to the input terminal of the peak amplifier 22 and the input terminal of the peak amplifier 24, the output terminal of the carrier amplifier 21 is connected to one end of the input side coil 301, the output terminal of the peak amplifier 22 is connected to one end of the phase shift line 41, the other end of the phase shift line 41 is connected to the other end of the input side coil 301, the output terminal of the peak amplifier 24 is connected to one end of the phase shift line 43, the other end of the phase shift line 43 is connected to one end of the input side coil 311, one end of the output side coil 312 is connected to the other end of the output side coil 302, and the other end of the input side coil 311 and the other end of the output side coil 312 are connected to the ground.

Accordingly, since the three amplifiers such as the carrier amplifier 21 and the peak amplifiers 22 and 24 are provided, the back-off amount, which is the difference in power from the high-output region in which the carrier amplifier 21 and the peak amplifiers 22 and 24 are in the on state to the low-output region in which only the carrier amplifier 21 is in the on state, can be secured in a stepwise and large manner. In addition, it is possible to suppress the decrease in the efficiency in the vicinity of the input power Ps and the deterioration in the efficiency in the maximum output power region, and it is possible to prevent the maximum output power from being insufficient.

In addition, for example, the high frequency circuit 1C according to the modification example 3 may further include the attenuator 54 connected between the connecting point between the output terminal of the preamplifier 23 and the input terminal of the peak amplifier 22, and the input terminal of the peak amplifier 24, and the attenuator 53 connected between the connecting point and the input terminal of the peak amplifier 22.

Accordingly, the signal power input to the peak amplifier 22 and the signal power input to the peak amplifier 24 can be controlled individually.

In addition, for example, the high frequency circuit according to the modification example 4 includes: the input terminal 111 and the output terminal 113; the carrier amplifier 21A, the peak amplifier 22A, the preamplifiers 11A and 23A; and the phase shift line 42A, in which the input terminal of the preamplifier 11A is connected to the input terminal 111, the output terminal of the preamplifier 11A is connected to the input terminal of the carrier amplifier 21A and the input terminal of the preamplifier 23A, the output terminal of the preamplifier 23A is connected to the input terminal of the peak amplifier 22A, the output terminal of the carrier amplifier 21A is connected to one end of the phase shift line 42A, and the output terminal of the peak amplifier 22A is connected to the other end of the phase shift line 42A.

Accordingly, the preamplifier 23A does not operate independently of the preamplifier 11A, but performs the pair operation with the preamplifier 11A. Accordingly, since the substantial gain of the preamplifier 23A is linked with that of the preamplifier 11A, it is possible to prevent the substantial gain of the preamplifier 23A from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23A from being relatively decreased alone, and it is possible to prevent the maximum output power from being insufficient.

In addition, for example, the high frequency circuit 1 and the high frequency circuit according to the modification example 4 are high frequency circuits having a Doherty amplifier, the high frequency circuits including the carrier amplifier 21 that amplifies the first high frequency signal to output the first amplified signal, the preamplifier 23 that amplifies the first high frequency signal to output the second amplified signal, the peak amplifier 22 that amplifies the second amplified signal to output the third amplified signal, and the combining circuit that combines the first amplified signal and the third amplified signal to output the combined signal.

Accordingly, the preamplifier 23 does not operate independently of the preamplifier 11, but performs the pair operation with the preamplifier 11. Accordingly, since the substantial gain of the preamplifier 23 is linked with that of the preamplifier 11, it is possible to prevent the substantial gain of the preamplifier 23 from being relatively increased alone, and it is possible to suppress the decrease in the efficiency in the vicinity of the input power Ps and the deterioration in the efficiency in the maximum output power region. In addition, it is possible to prevent the substantial gain of the preamplifier 23 from being relatively decreased alone, and it is possible to prevent the maximum output power from being insufficient.

The communication apparatus 4 according to the present exemplary embodiment includes the RFIC 3 that processes the high frequency signal, and the high frequency circuit 1 that transmits the high frequency signal between the RFIC 3 and the antenna 2.

Accordingly, the communication apparatus 4 can realize the effects of the high frequency circuit 1.

### OTHER EMBODIMENTS

Although the high frequency circuit and the communication apparatus according the present disclosure has been described with reference to the exemplary embodiment and the modification examples, the high frequency circuit and the communication apparatus according to the present disclosure is not limited to the exemplary embodiment and the modification examples described above. The present disclosure also includes another embodiments realized by combining any of the constituent elements in the exemplary embodiment and the modification examples described above, a modification example obtained by making various modifications that can be conceived of by those skilled in the art with respect to the exemplary embodiment and the modification examples described above within a range that does not deviate from the gist of the present disclosure, or various devices in which the high frequency circuit and the communication apparatus are built.

In addition, for example, in the high frequency circuit and the communication apparatus according to the exemplary embodiment and the modification examples described above, another circuit element, another wiring, or the like may be inserted into the path for connecting the circuit elements and the signal paths disclosed in the drawings.

The claimed subject matter can be widely used in a communication device such as a mobile phone, as a high frequency circuit disposed in a multi-band compatible front end portion.

### REFERENCE SIGNS LIST

1, 1A, 1B, 1C, 500 high frequency circuit
2 antenna
3 RF signal processing circuit (RFIC)
4 communication apparatus
10, 10A, 10B, 10C, 10D, 10E, 510, 510E amplification circuit
11, 11A, 11B, 12, 23, 23A, 23B preamplifier
21, 21A, 21B carrier amplifier
22, 22A, 22B, 24 peak amplifier
30, 31, 32, 33, 34 transformer
41, 42A, 42B, 43 phase shift line
50 phase shift circuit
51, 53, 54 attenuator
52, 56 capacitor
55A, 55B, 71, 72 matching circuit
61, 64 switch
62, 63 filter
73, 74 bias circuit
80, 580 semiconductor IC
100 antenna connection terminal
110, 111, 112 input terminal
113 output terminal
301, 311 input side coil
302, 312 output side coil

1. A high frequency circuit comprising:
a signal input terminal and a signal output terminal;
a first amplifier, a second amplifier, a third amplifier, and a fourth amplifier; and
a first phase shift circuit, wherein
an input terminal of the fourth amplifier is connected to the signal input terminal,
an output terminal of the fourth amplifier is connected to an input terminal of the first amplifier and an input terminal of the second amplifier,
an output terminal of the second amplifier is connected to an input terminal of the third amplifier,
an output terminal of the third amplifier is connected to one end of the first phase shift circuit, and
the other end of the first phase shift circuit is connected to an output terminal of the first amplifier.

2. The high frequency circuit according to claim 1, further comprising:
a first transformer including a first input side coil and a first output side coil, wherein
one end of the first input side coil is connected to the output terminal of the first amplifier,
another end of the first input side coil is connected to the other end of the first phase shift circuit, and
one end of the first output side coil is connected to the signal output terminal.

3. The high frequency circuit according to claim 1, further comprising:
a first attenuator connected between the output terminal of the fourth amplifier and the input terminal of the third amplifier.

4. The high frequency circuit according to claim 1, further comprising:
a capacitor disposed in series to a path that connects the output terminal of the first amplifier and the output terminal of the second amplifier.

5. The high frequency circuit according to claim 1, further comprising:
a first matching circuit connected between the output terminal of the fourth amplifier and a connecting point between the input terminal of the first amplifier and the input terminal of the second amplifier.

6. The high frequency circuit according to claim 5, further comprising:
a second matching circuit connected between the output terminal of the second amplifier and the input terminal of the third amplifier.

7. The high frequency circuit according to claim 2, further comprising:
a fifth amplifier;
a second phase shift circuit; and
a second transformer having a second input side coil and a second output side coil, wherein
the output terminal of the second amplifier is connected to the input terminal of the third amplifier and an input terminal of the fifth amplifier,
an output terminal of the fifth amplifier is connected to one end of the second phase shift circuit,
the other end of the second phase shift circuit is connected to one end of the second input side coil,
one end of the second output side coil is connected to the other end of the first output side coil, and
the other end of the second input side coil and the other end of the second output side coil are connected to a ground.

8. The high frequency circuit according to claim 7, further comprising:
a second attenuator connected between a connecting point between the output terminal of the second amplifier and the input terminal of the third amplifier, and the input terminal of the fifth amplifier.

9. A communication apparatus, comprising:
the high frequency circuit according to claim 7,
a signal processing circuit that processes a high frequency signal, and
an antenna,
wherein the high frequency signal is transmitted between the signal processing circuit and the antenna.

10. A high frequency circuit comprising:
a semiconductor integrated circuit (IC) including a first amplifier, a second amplifier, a third amplifier, and a fourth amplifier,
wherein, in a plan view of a main surface of the semiconductor IC, the second amplifier is disposed between the first amplifier and the third amplifier.

11. The high frequency circuit according to claim 10,
wherein, in the plan view of the main surface of the semiconductor IC, a size of an amplification transistor constituting the second amplifier is smaller than a size of an amplification transistor constituting the first amplifier and smaller than a size of an amplification transistor constituting the fourth amplifier.

12. The high frequency circuit according to claim 10, further comprising:
a first transformer including a first input side coil and a first output side coil, wherein
one end of the first input side coil is connected to an output terminal of the first amplifier,
the other end of the first input side coil is connected to one end of a first phase shift circuit, and
one end of the first output side coil is connected to a signal output terminal.

13. The high frequency circuit according to claim 10, further comprising:
a first attenuator connected between an output terminal of the fourth amplifier and an input terminal of the third amplifier.

14. The high frequency circuit according to claim 10, further comprising:
a capacitor disposed in series to a path that connects an output terminal of the first amplifier and an output terminal of the second amplifier.

15. The high frequency circuit according to claim 10, further comprising:
a first matching circuit connected between an output terminal of the fourth amplifier and a connecting point between an input terminal of the first amplifier and an input terminal of the second amplifier.

16. The high frequency circuit according to claim 15, further comprising:
a second matching circuit connected between an output terminal of the second amplifier and an input terminal of the third amplifier.

17. The high frequency circuit according to claim 12, further comprising:
a fifth amplifier;
a second phase shift circuit; and
a second transformer having a second input side coil and a second output side coil, wherein
an output terminal of the second amplifier is connected to an input terminal of the third amplifier and an input terminal of the fifth amplifier,
an output terminal of the fifth amplifier is connected to one end of the second phase shift circuit,
the other end of the second phase shift circuit is connected to one end of the second input side coil,
one end of the second output side coil is connected to the other end of the first output side coil, and
the other end of the second input side coil and the other end of the second output side coil are connected to a ground.

18. The high frequency circuit according to claim 17, further comprising:
a second attenuator connected between a connecting point between the output terminal of the second amplifier and the input terminal of the third amplifier, and the input terminal of the fifth amplifier.

19. A high frequency circuit having a Doherty amplifier, the high frequency circuit comprising:
a first amplifier that amplifies a first high frequency signal to output a first amplified signal;
a second amplifier that amplifies the first high frequency signal to output a second amplified signal;
a third amplifier that amplifies the second amplified signal to output a third amplified signal; and
a combining circuit that combines the first amplified signal and the third amplified signal to output a combined signal.
